(19) United States
(12) Patent Application Publication
(10) Pub. No.: US 2026/0003094 A1
(43) Pub. Date: Jan. 1, 2026

(54) PROXIMITY SENSOR AND AMPLIFIER HOUSING

(71) Applicant: Keyence Corporation, Osaka (JP)

(72) Inventor: Masaki WADA, Osaka (JP)

(73) Assignee: Keyence Corporation, Osaka (JP)

(21) Appl. No.: 19/210,141

(22) Filed: May 16, 2025

(30) Foreign Application Priority Data
Jun. 28, 2024 (JP) 2024-104551

(51) Int. Cl. G01V 3/10; H03F 3/04

(52) U.S. Cl. CPC G01V 3/10; H03F 3/04

(57) ABSTRACT

The proximity sensor includes a detection coil, a metal head housing, and a power supply cable. The detection coil generates a detection current. The metal head housing houses the detection coil. The power supply cable has an electrical connection with the detection coil and is connected to the metal head housing. At least a part of an internal space of the metal head housing is filled with a filler so as to bury the detection coil. As the filler, an adhesive and an additive having a relative permittivity lower than that of the adhesive are mixed.

### CROSS-REFERENCE TO RELATED APPLICATIONS

The present application claims foreign priority based on Japanese Patent Application No. 2024-104551, filed Jun. 28, 2024, the contents of which are incorporated herein by reference.

### BACKGROUND OF THE INVENTION

### 1. Technical Field

The invention relates to a proximity sensor and an amplifier housing.

### 2. Description of the Related Art

CN202853631U discloses a proximity sensor that detects a detection object. In the proximity sensor described in CN202853631U, a head board 16 (main circuit board) is housed in a head shaft body (housing 11). When the head shaft body (housing 11) is of a shorter type, it is easy to dispose the head shaft body even in an environment with an obstacle, while a distance between the head shaft body (housing 11) and a detection object becomes long. When the distance between the head shaft body (housing 11) and the detection object becomes long, a change in a magnetic field for detecting the detection object becomes weak.

### SUMMARY OF THE INVENTION

In order to capture this weak change, a pulse type (a type of applying a pulse-shaped excitation current) may be used.

In the proximity sensor described in CN202853631U, in a case where the pulse type is used, even though the weak change in the magnetic field can be captured, calculation based on the change in the magnetic field becomes complicated. Accordingly, since a size of a board on which a control circuit for calculation is implemented is increased, a size of the head shaft body (housing 11) that houses the board is also inevitably increased.

The invention has been made in view of the above problems, and an object of the invention is to provide a proximity sensor and an amplifier housing that can downsize a head shaft body while realizing a long detection distance.

A proximity sensor according to one embodiment of the invention detects a detection object. The proximity sensor includes a detection coil, a head housing, a power supply cable, a transmission circuit, a reception circuit, a control circuit, an amplifier board, and an amplifier housing. The detection coil generates a magnetic field for detection. The head housing houses the detection coil. The power supply cable is a cable that is connected to the head housing to supply power to the detection coil. The transmission circuit supplies a pulse-shaped excitation current to the detection coil. The reception circuit detects a detection current generated in the detection coil. The control circuit outputs a result of detecting the detection object based on a reception signal from the reception circuit that has detected the detection current. The control circuit is implemented on the amplifier board. The amplifier housing houses the amplifier board. The head housing includes a detection surface, a connecting portion, and a fixed portion. The connecting portion is positioned on an opposite side of the head housing from the detection surface in a normal direction of the detection surface, and the power supply cable is connected to the connecting portion. The fixed portion is positioned between the detection surface and the connecting portion in the normal direction of the detection surface, and comes into contact with a fixture for fixing the head housing to an external member when the head housing is fixed to the external member. The amplifier housing is disposed outside the head housing.

An amplifier according to another embodiment of the invention is included in a proximity sensor. The proximity sensor includes a head, a power supply cable, an amplifier, a transmission circuit, a reception circuit, and a control circuit. The head includes a head housing that houses a detection coil that generates a magnetic field for detection. The power supply cable is connected to the head housing. The transmission circuit supplies a pulse-shaped excitation current to the detection coil. The reception circuit detects a detection current generated in the detection coil. The control circuit outputs a result of detecting a detection object based on a reception signal from the reception circuit that has detected the detection current. The amplifier is electrically connected to the head via the power supply cable. An amplifier includes an amplifier board to which a core wire included in the power supply cable is connected and on which the control circuit is implemented, and an amplifier housing that houses the amplifier board.

According to the proximity sensor and the amplifier housing of the invention, the head shaft body can be downsized.

### BRIEF DESCRIPTION OF THE DRAWINGS

FIG. 1 is a schematic configuration diagram of a proximity sensor;

FIG. 2 is a perspective view of an L-type proximity sensor;

FIG. 3 is a perspective view of a cylinder-type proximity sensor;

FIG. 4 is a perspective view of a flat-type proximity sensor;

FIG. 5 is a longitudinal sectional view of the L-type proximity sensor;

FIG. 6 is an enlarged perspective view of a longitudinal section of a front portion of a head housing;

FIG. 7 is a double logarithmic graph with a horizontal axis and a vertical axis as frequency-skin depth, and a schematic view for explaining the double logarithmic graph;

FIG. 8 is a perspective view of a longitudinal section of the head housing;

FIG. 9 is an enlarged perspective view illustrating a detection coil and a device related to the detection coil;

FIG. 10A is a graph representing an image of a reception waveform subjected to zero adjustment in a case where there is no external member and a detection object is not within a detection range;

FIG. 10B is a graph representing an image of a reception waveform subjected to zero adjustment in a case where there is no external member and the detection object is within the detection range;

FIG. 11A is a graph representing an image of a reception waveform subjected to zero adjustment in a case where there is an external member and the detection object is not within the detection range;

FIG. 11B is a graph representing an image of a reception waveform subjected to zero adjustment in a case where there is an external member and the detection object is within the detection range;

FIG. 12 is a partially cut perspective view of the cylinder-type proximity sensor; and

FIG. 13 is an enlarged perspective view of a longitudinal section of the flat-type proximity sensor.

### DETAILED DESCRIPTION

Hereinafter, embodiments of the invention will be described with reference to the drawings. Note that, in the drawings, the same or corresponding portions are denoted by the same reference numerals, and the description thereof will not be repeated.

In the following description, terms meaning positions or directions such as “front” and “rear” may be used. These terms are used for the sake of convenience to facilitate understanding of the embodiments, and are not related to directions in which actions are actually implemented unless otherwise expressly stated.

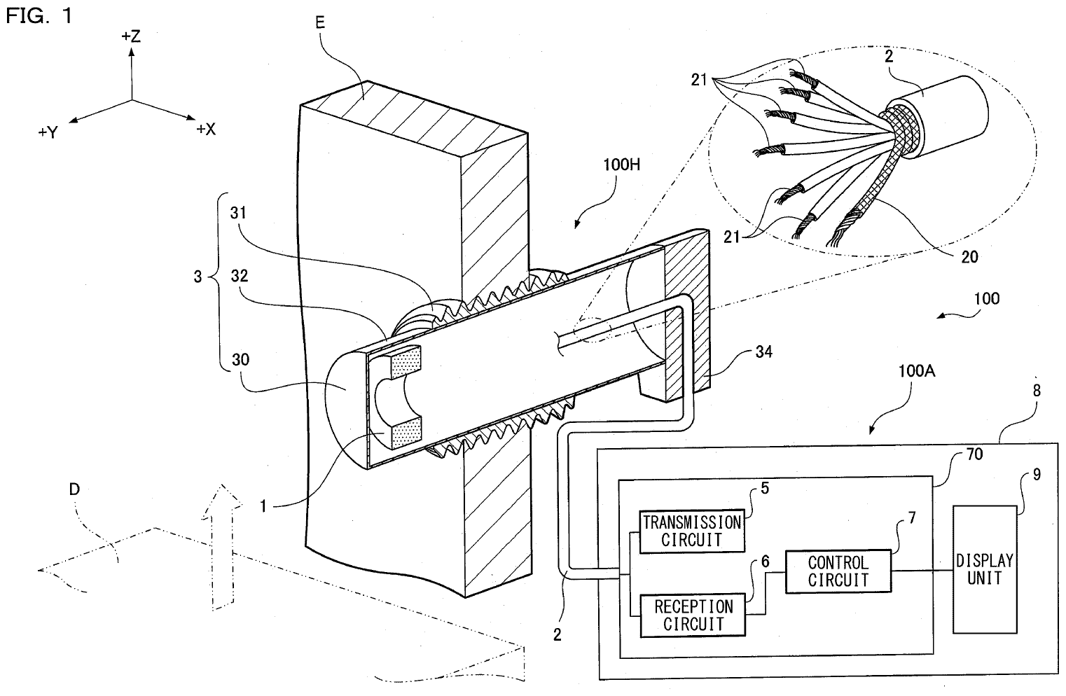

Hereinafter, a proximity sensor 100 according to an embodiment of the invention will be described with reference to the drawings. First, an outline of the proximity sensor 100 will be described with reference to FIG. 1. FIG. 1 is a schematic configuration diagram of the proximity sensor 100. FIG. 1 illustrates arrows X, Y, and Z indicating three directions orthogonal to each other. The directions indicated by arrows X, Y, and Z all correspond to disposition postures of the proximity sensor 100, and the direction indicated by arrow X is referred to as an X-axis direction, the direction indicated by arrow Y is referred to as a Y-axis direction, and the direction indicated by arrow Z is referred to as a Z-axis direction. One of the directions along the X-axis direction is referred to as a +X direction, and the other is referred to as a −X direction. One of the directions along the Y-axis direction is referred to as a +Y direction, and the other is referred to as a −Y direction. One of the directions along the Z-axis direction is referred to as a +Z direction, and the other is referred to as a −Z direction.

The proximity sensor 100 is a sensor that detects the presence or absence or a position of a detection object D. As illustrated in FIG. 1, the proximity sensor 100 includes a head 100H, an amplifier 100A, and a power supply cable 2 connecting the head 100H and the amplifier 100A. The head 100H includes a detection coil 1 and a head housing 3 that houses the detection coil 1. The amplifier 100A includes a transmission circuit 5, a reception circuit 6, a control circuit 7, an amplifier board 70 on which the transmission circuit 5, the reception circuit 6, and the control circuit 7 are provided, and an amplifier housing 8 that houses the amplifier board 70.

The detection coil 1 generates a magnetic field for detection. The power supply cable 2 is a member for supplying power to the detection coil 1, and power is supplied to the detection coil 1 from a power supply (not illustrated) via the power supply cable 2. The head housing 3 houses the detection coil 1. The head housing 3 is disposed such that a normal direction of a detection surface 30 to be described later is along the Y-axis direction, and the detection surface 30 faces the +Y direction side. The head housing 3 of the present embodiment has a shape whose longitudinal direction is along the Y-axis direction, and includes a connecting portion 34 that guides the power supply cable 2 to the −Y direction side.

The transmission circuit 5 supplies a pulse-shaped excitation current to the detection coil 1. The reception circuit 6 detects a detection current generated in the detection coil 1. The control circuit 7 detects the presence or absence or the position of the detection object D based on a reception signal from the reception circuit 6 that has detected the detection current. Since the detection current changes in accordance with a change in the magnetic field, the change in the magnetic field is reflected in the reception signal from the reception circuit 6. The control circuit 7 outputs a result of detecting the presence or absence or the position of the detection object D.

The transmission circuit 5, the reception circuit 6, and the control circuit 7 are implemented on the amplifier board 70. The power supply cable 2 electrically connects the detection coil 1 and the amplifier board 70. Although the transmission circuit 5, the reception circuit 6, and the control circuit 7 are implemented on the amplifier board 70 in the present embodiment, at least the control circuit 7 may be implemented. For example, a board on which the transmission circuit 5 and the reception circuit 6 are implemented may be housed in the head housing 3.

The head housing 3 includes a detection surface 30 disposed at an end portion of the head housing 3 on the +Y direction side, and a head cylindrical portion 32 having a circumferential shape of which a center line is along the Y-axis direction. The head cylindrical portion 32 has a fixed portion 31. The fixed portion 31 is provided between the connecting portion 34 and the detection surface 30 in the Y-axis direction, and is a portion to which a fastening member such as a nut (not illustrated) is fastened when the head housing 3 is fixed to an external member E.

The amplifier housing 8 houses the amplifier board 70. The amplifier housing 8 is disposed outside the head housing 3.

Generally, a proximity sensor using an induced current is a product having a short detection distance to such an extent that the product collides with the detection object D when the detection object D is deviated from an assumed movement path. Thus, when a long detection distance is realized in the proximity sensor using the induced current, a risk of colliding with the detection object D is reduced. The proximity sensor 100 using the induced current includes a sinusoidal type in which a sinusoidal excitation current is applied to the detection coil 1 and a pulse type in which a pulse-shaped excitation current is applied to the detection coil 1. Both the types detect the change in the current generated in the detection coil 1, but a change in the current becomes weaker as a distance between the detection object D and the detection coil 1 is longer. That is, in order to realize a long detection distance, it is necessary to capture a slight change, but in the sinusoidal type, it is difficult to distinguish between the detection object D and a metal body (external member E) other than the detection object D. In the type in which the pulse-shaped excitation current is supplied to the detection coil 1, since a signal having a characteristic change in a time axis starting from an excitation timing can be obtained as the reception signal obtained in accordance with the excitation current, more information can be obtained than the sinusoidal type. For example, it is possible to perform calculation using an attenuation time from a peak of the reception signal in order to distinguish between the detection object D and the metal body other than the detection object D or perform processing by matching time axes of a plurality of reception signals generated in a plurality of detection coils 1. Thus, the pulse type has an advantage that detection accuracy by calculation can be improved as compared with the sinusoidal type. The proximity sensor 100 of the present embodiment is a pulse-type proximity sensor that is the type in which the pulse-shaped excitation current is supplied to the detection coil 1. The pulse type requires complicated processing such as control of an application timing of the pulse-shaped excitation current to the coil and processing of a current generated in the coil. Accordingly, in order to realize a long detection distance, when the detection object D is to be detected by the pulse type, the control circuit 7 that performs relatively complicated processing is required, and the amplifier board 70 on which the control circuit 7 is implemented becomes large.

Accordingly, the proximity sensor 100 according to the present embodiment can downsize the head housing 3 while realizing a long detection distance by housing the amplifier board 70 in the amplifier housing 8 separate from the head housing 3. In particular, in the present embodiment, since a dimension in the Y-axis direction can be reduced, the proximity sensor 100 can be disposed even in a case where a sufficient installation space is not provided in the Y-axis direction with respect to the external member E.

As illustrated in an enlarged manner in FIG. 1, the power supply cable 2 includes a core wire 21 through which the detection current flows and a shield sheath 20 that covers the core wire 21 with a shield. The shield sheath 20 is electrically connected to an electric shield 43 to be described later. Note that, the shield sheath 20 and the electric shield 43 may be electrically connected, and may be directly connected or indirectly connected. Since the core wire 21 through which the detection current flows is covered with the shield sheath 20, the change in the detection current is hardly influenced by an outside. As described above, as a distance between the detection object D and the detection coil 1 is longer, the change in the detection current is weaker. In particular, in such a case, the detection accuracy of the detection object D having a longer distance from the detection coil 1 is improved by adopting a configuration in which the detection current is hardly influenced by the outside. Accordingly, according to the configuration in which the core wire 21 is shielded, the detection accuracy of the proximity sensor 100 is improved.

The amplifier 100A includes a display unit 9 (for example, an indicator lamp) that displays a result output from the control circuit 7. The display unit 9 is provided on a front surface of the amplifier housing 8. The display unit 9 is provided on the front surface of the amplifier housing 8, and thus, a user can easily grasp the detection result by the proximity sensor 100 by visually recognizing the amplifier housing 8.

The head cylindrical portion 32 is made of metal, and a part thereof is processed as the fixed portion 31. In the fixed portion 31, a circumferential screw groove on a circumference with the Y-axis direction as a center line is formed. A screw hole in which a screw groove corresponding to the screw groove formed in the fixed portion 31 is cut is provided in the external member E. In a case where the fixed portion 31 is a male screw, the screw hole provided in the external member E is a female screw. The external member E and the fixed portion 31 are fixed by screwing. In a case where the external member E and the fixed portion 31 are screwed, a nut (not illustrated) may be screwed to the fixed portion 31 to further stabilize a positional relationship between the external member E and the head housing 3 in the Y-axis direction. In particular, when the head housing 3 is disposed such that the head housing 3 does not protrude toward the +Y direction side with respect to the external member E, that is, the path side of the detection object D in the Y-axis direction, the external member E and the fixed portion 31 are often fixed by screwing. Thus, the nut is preferably fitted to the fixed portion 31 positioned on the −Y direction side with respect to the external member. Note that, in the present embodiment, the screw hole is provided in the external member E, and the head housing 3 is fixed to the external member E by screwing the fixed portion 31 into the screw hole. However, in a state where the head housing 3 is disposed in a through-hole provided in the external member E, the head housing 3 may be configured to be fixed to the external member E by sandwiching the external member E between a nut screwed to the fixed portion 31 positioned on the +Y direction side with respect to the external member E and a nut screwed to the fixed portion 31 positioned on the −Y direction side with respect to the external member E.

Accordingly, the metal fixed portion 31 is the screw groove, and thus, the proximity sensor 100 can be easily fixed to the external member E. In the present embodiment, the screw groove is provided in the fixed portion 31, but may be made of metal such that the positional relationship between the external member E and the head housing 3 is stabilized when the head housing 3 is fixed to the external member E. The head housing 3 may be fixed to the external member E by attaching a clamp to the metal fixed portion 31 and fixing the clamp to the external member E.

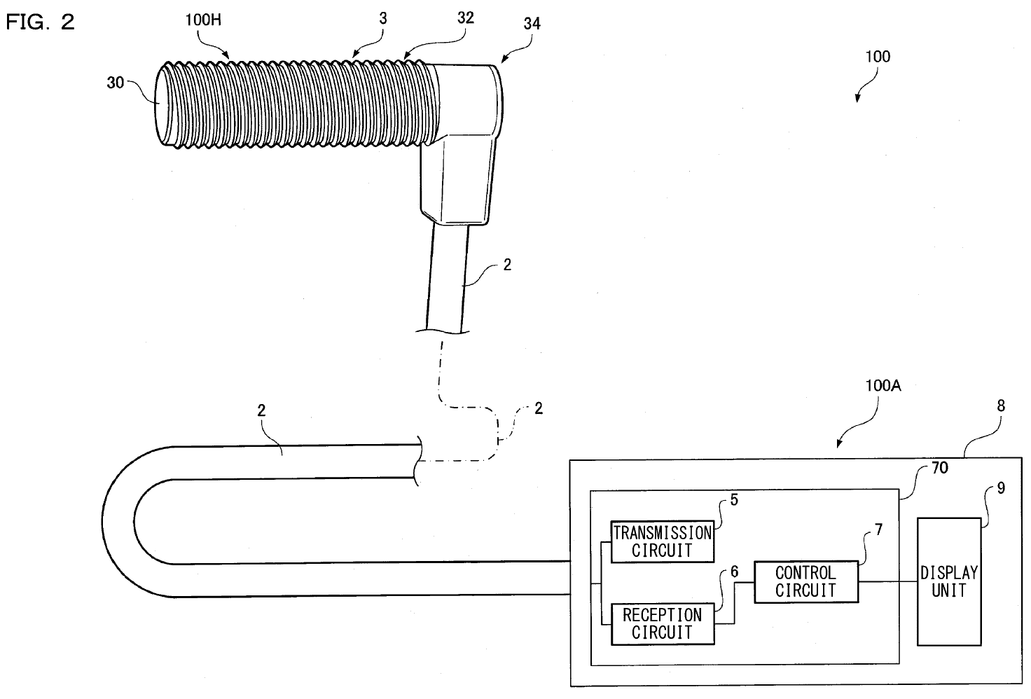

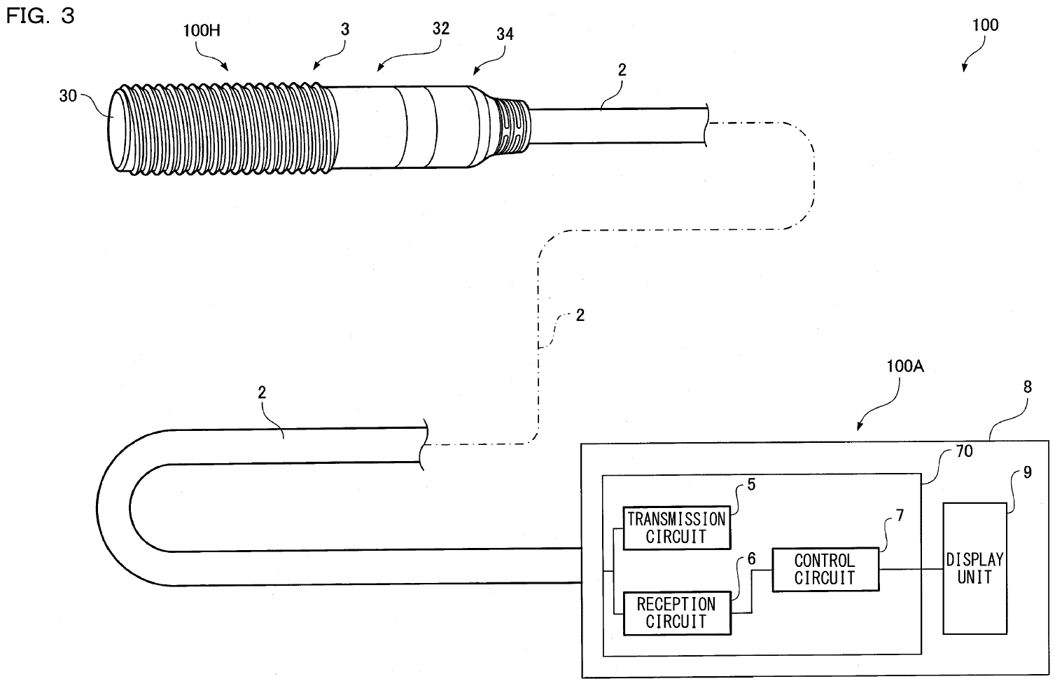

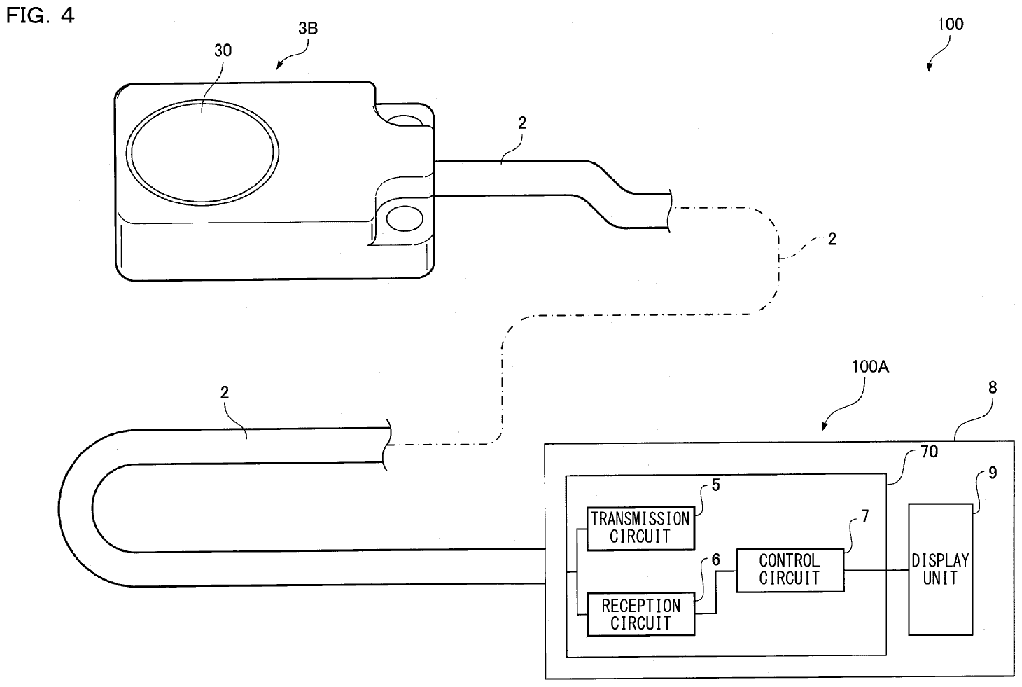

Hereinafter, variations of the proximity sensor 100 will be described with reference to FIGS. 2 to 4. FIG. 2 is a perspective view of an L-type proximity sensor 100. FIG. 3 is a perspective view of a cylinder-type proximity sensor 100. FIG. 4 is a perspective view of a flat-type proximity sensor 100.

The proximity sensor 100 illustrated in FIG. 2 is also referred to as an L-type because a side view of a structure having the detection surface 30 which is the head housing 3 of the head 100H including the detection coil 1 (not illustrated) is L-shaped. Since the structure having the detection surface 30 is cylindrical, the proximity sensor 100 illustrated in FIG. 3 is also referred to as a cylinder-type. The proximity sensor 100 illustrated in FIG. 4 is also referred to as a flat-type because the structure having the detection surface 30 is box-shaped (has a flat surface).

Each type of proximity sensor 100 illustrated in FIGS. 2 to 4 includes the head housing 3 that is the structure having the detection surface 30, and the amplifier housing 8 separate from the head housing 3. As illustrated in FIGS. 2 and 3, in the L-type proximity sensor 100 and the cylinder-type proximity sensor 100, the head housing 3 includes the detection surface 30 and a columnar head cylindrical portion 32 with a normal direction of the detection surface as a center line. The head housing 3 of the L-type proximity sensor 100 and the head housing 3 of the cylinder-type proximity sensor 100 have elongated shapes such that the axial direction of the head cylindrical portion 32 is the longitudinal direction. On the other hand, as illustrated in FIG. 4, the flat-type proximity sensor 100 includes a box-shaped head housing 3B, and the head housing 3B has the detection surface 30.

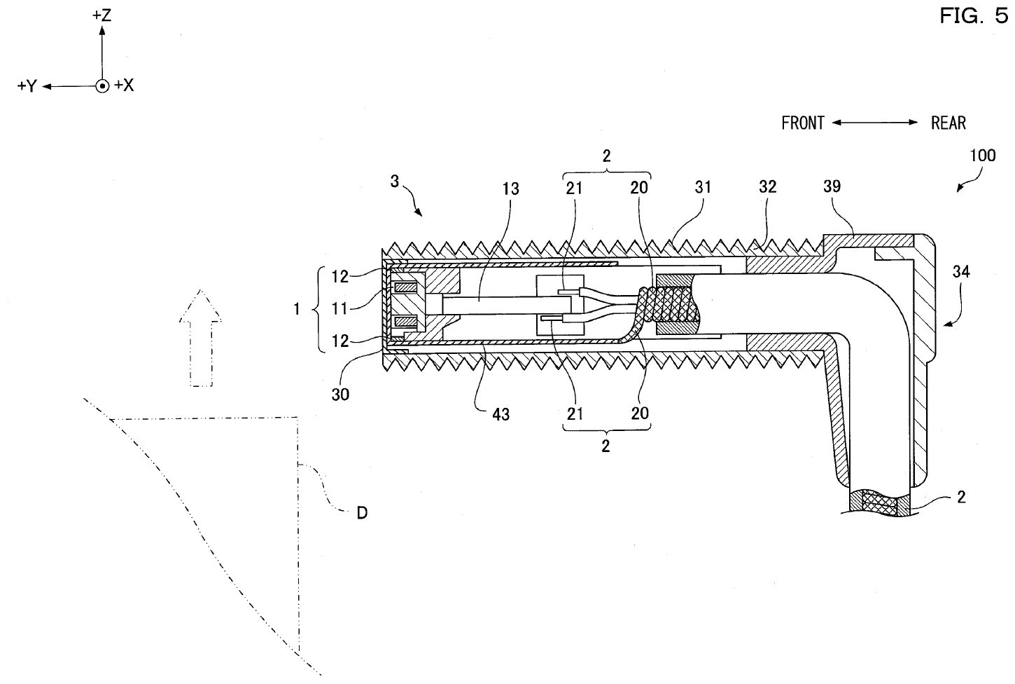

Hereinafter, the L-type proximity sensor 100 will be described with reference to FIGS. 5 to 9. First, the L-type proximity sensor 100 will be described in detail with reference to FIG. 5. FIG. 5 is a longitudinal sectional view of the L-type proximity sensor 100.

As illustrated in FIG. 5, the proximity sensor 100 includes the detection coil 1, the power supply cable 2, and the head housing 3.

The detection coil 1 generates a magnetic field for detection. The power supply cable 2 is a member for supplying power to the detection coil 1. The head housing 3 houses the detection coil 1. The head housing 3 is disposed such that the normal direction of the detection surface 30 is along the Y-axis direction, and the detection surface 30 faces the +Y-direction side. The head housing 3 of the present embodiment has an elongated shape whose longitudinal direction is along the Y-axis direction, and includes the connecting portion 34 that guides the power supply cable 2 to the −Y direction side.

The head housing 3 has the detection surface 30 made of metal on the +Y direction side of the head housing 3. Since the detection coil 1 is disposed near the detection surface 30, the detection coil 1 is disposed on the +Y direction side of the head housing 3. The head housing 3 has an elongated shape in the Y-axis direction, and the detection coil 1 is disposed such that a −Y-direction-side end portion of the detection coil 1 is positioned on the +Y-direction side with respect to the connecting portion 34, in other words, the detection coil 1 and the connecting portion 34 are separated from each other in the Y-axis direction.

The connecting portion 34 is disposed on the −Y direction side of the head housing 3 and guides the power supply cable 2 in the −Z direction.

Hereinafter, for the sake of convenience, the −Y direction side of the head housing 3 may be referred to as one end side of the head housing 3 in the longitudinal direction, in other words, the connecting portion 34 side, and the +Y direction side of the head housing 3 may be referred to as the other end side of the head housing 3 in the longitudinal direction, in other words, the detection surface 30 side. In addition, the −Y direction side may be referred to as a rear side, and the +Y direction side may be referred to as a front side.

The head housing 3 illustrated in FIG. 5 has a shape in which the connecting portion 34 guides the power supply cable 2 in the −Z direction, and thus, the head housing has an L shape in side view (as viewed in the X-axis direction). That is, the connecting portion 34 does not extend rearward along the Y-axis direction, which is the normal direction of the detection surface 30, but extends in a direction intersecting a front-back direction (longitudinal direction), which is the Y-axis direction.

Thus, the L-type proximity sensor 100 in which the head housing 3 is L-shaped is suitable in a case where there is an obstacle behind the head housing 3. This is because, as compared with the proximity sensor 100 in which the head housing 3 is not L-shaped, when the head housing 3 is fixed to the external member E, the head housing 3 hardly interferes with the obstacle positioned behind the external member E. However, in a case where a distance between the external member E and an obstacle positioned on the −Y direction side with respect to the external member E is short in the Y-axis direction, that is, the front-back direction, the head 100H needs to be disposed close to the +Y direction side (front side) even in the L-type proximity sensor 100. That is, since the head housing 3 is disposed such that the detection surface 30 of the head housing 3 is closer to the path of the detection object D, a possibility of collision between the detection object D and the detection surface 30 increases. Here, the detection surface 30 having a risk of colliding with the detection object D is made of metal, and thus, strength is increased. As a result, a failure of the head 100H due to the collision with the detection object D can be reduced. Accordingly, the proximity sensor 100 can achieve both a degree of freedom of disposition that can be installed even in an environment where the obstacle is positioned behind the external member E and the reduction of the failure of the head 100H.

Note that, in the present embodiment, the connecting portion 34 is configured to guide the power supply cable 2 in the −Z direction, but may be configured to guide the power supply cable 2 in a direction intersecting the normal direction of the detection surface 30. In addition, the direction in which the power supply cable 2 is guided by the connecting portion 34 is preferably closer to the Y-axis direction, that is, a direction orthogonal to the longitudinal direction (front-back direction). Accordingly, the head housing 3 more hardly interferes with the obstacle positioned behind the head housing 3.

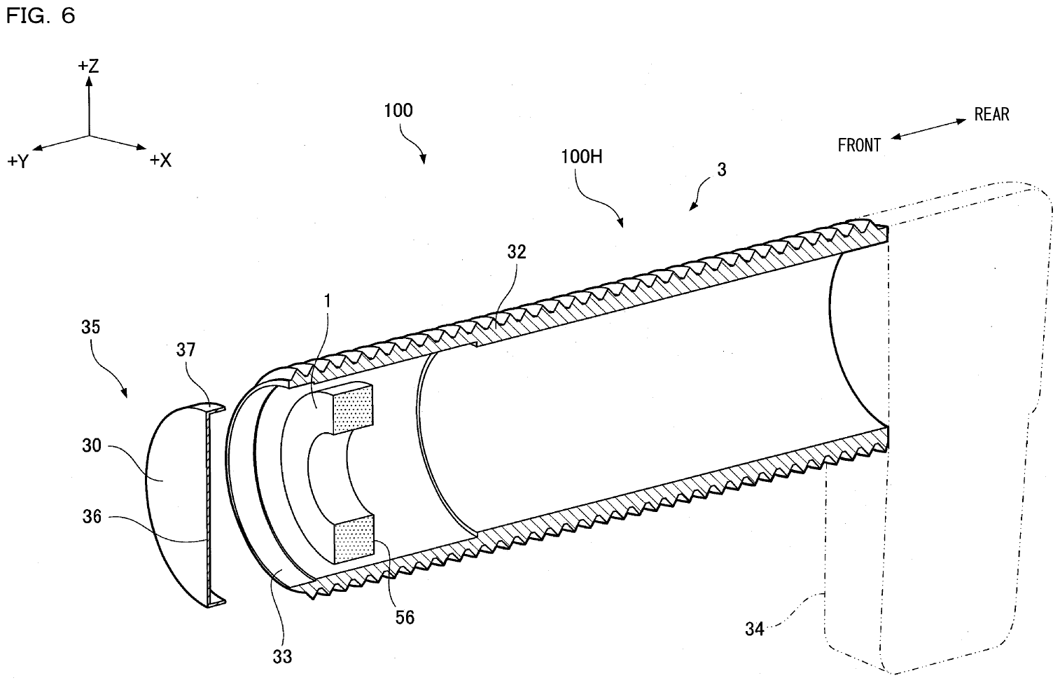

Next, the head housing 3 of the proximity sensor 100 will be described in detail with reference to FIG. 6. FIG. 6 is a perspective view of a longitudinal section of a site (other end portion) on the +Y direction side of the head housing 3. In FIG. 6, for the sake of convenience, components other than the detection coil 1 are omitted in the head housing 3.

As illustrated in FIG. 6, the head housing 3 includes the head cylindrical portion 32 (body portion) made of metal and a cap portion 35 made of metal. The head cylindrical portion 32 is a cylindrical member having a peripheral surface on a circumference whose center line is along the Y-axis direction and having an opening toward the +Y direction side. The cap portion 35 is attached to the head cylindrical portion 32 to cover the opening of the head cylindrical portion 32 from the +Y direction side (front end side) of the head cylindrical portion 32. The cap portion 35 attached to the head cylindrical portion 32 is positioned on a front end side of the head housing 3. The cap portion 35 includes the detection surface 30 made of metal.

Since the cap portion 35 separate from the head cylindrical portion 32 includes the detection surface 30, the head cylindrical portion 32 has a shape in which not only a rear end portion but also a front end portion of the head cylindrical portion 32 is opened. Accordingly, an inner peripheral surface of the head cylindrical portion 32 can be cut (thinned) from both end sides of the front end portion and the rear end portion. As compared with the configuration in which the detection surface 30 is provided integrally with the head cylindrical portion 32, since cutting can be performed from both end sides in the Y-axis direction, a degree of difficulty in manufacturing is reduced.

More specifically, cutting (recession) is generally performed by inserting a drill, which is a cutting blade, into the head cylindrical portion 32 while rotating the drill. The longer the drill, the larger deflection of a drill tip.

In the configuration in which the detection surface 30 is provided integrally with the head cylindrical portion 32, the drill is inserted only from the rear end portion side of the head cylindrical portion 32. For this reason, it is necessary to use a long drill to cut the front end portion side of the head cylindrical portion 32, and the deflection of the drill tip becomes large. Accordingly, it is difficult to maintain the accuracy of cutting (thinning) at the front end portion of the head cylindrical portion.

Since the front end portion of the head cylindrical portion is a portion where the detection coil 1 is disposed, high accuracy is required for cutting (thinning). Accordingly, in the head cylindrical portion in which only the rear end portion is opened, the degree of difficulty in manufacturing is high.

On the other hand, in the configuration in which the cap portion 35 including the detection surface 30 is separately provided as in the head cylindrical portion 32 illustrated in FIG. 6, a drill rotating from both end sides of the front end portion and the rear end portion of the head cylindrical portion 32 is inserted. Thus, even in a case where the front end portion side of the head cylindrical portion 32 is cut, the drill can be inserted from the front end portion side of the head cylindrical portion 32. Accordingly, since cutting can be performed by selecting a relatively short drill in which the tip side of the rotating drill easily swings, the accuracy of cutting (thinning) is improved. As a result, in the proximity sensor 100, the head housing 3 includes the detection surface 30 and the cap portion 35 separate from the head cylindrical portion 32, and thus, the front end portion and the rear end portion of the head cylindrical portion 32 are opened. As a result, the degree of difficulty in manufacturing can be reduced.

The head cylindrical portion 32 has an abutment portion 33 on the inner peripheral surface. The abutment portion 33 abuts on the cap portion 35 in a state of being appropriately attached to the head cylindrical portion 32. The cap portion 35 is fixed to the head cylindrical portion 32 with an adhesive while abutting on the abutment portion 33.

Accordingly, since the cap portion 35 is easily appropriately attached to the head cylindrical portion 32, the degree of difficulty in manufacturing the proximity sensor 100 is reduced.

The abutment portion 33 is a circumferential groove having a predetermined width from a +Y direction side end portion (front end) of the head cylindrical portion 32 toward the −Y direction side (rear side) on the inner peripheral surface of the head cylindrical portion 32. The predetermined width of the circumferential groove corresponds to a dimension of the cap portion 35 in the Y-axis direction (front-back direction) attached to the head cylindrical portion 32. An inner diameter of the circumferential groove is slightly larger than an outer diameter of the cap portion 35 (by the amount that the adhesive enters). Accordingly, the circumferential groove which is the abutment portion 33 functions as positioning of the cap portion 35.

The cap portion 35 has a bottom portion 36 including the detection surface 30 and a peripheral portion 37 erected from an outer peripheral edge of the bottom portion 36. In a state where the cap portion 35 is attached to the head cylindrical portion 32, an end of the peripheral portion 37 on the −Y direction (connecting portion 34) side (rear end of the peripheral portion 37) is positioned on the +Y direction side, that is, on the front side with respect to an end of the detection coil 1 on the −Y direction (connecting portion 34) side (rear end 56 of the detection coil 1).

Since the cap portion 35 does not become longer than necessary in the front-back direction, a degree of difficulty in cutting the cap portion 35 itself hardly increases. Accordingly, the degree of difficulty in manufacturing the proximity sensor 100 is reduced.

In the head cylindrical portion 32, a portion including an end of the detection coil 1 on the −Y direction side (connecting portion 34 side), that is, a portion on the +Y direction side with respect to a rear end 56 of the detection coil 1 (front portion) is a thin portion thinner than other portions.

Accordingly, since the head cylindrical portion 32 is formed to be relatively thin around an outer periphery of the detection coil 1, the magnetic field from the detection coil 1 is hardly hindered by the head cylindrical portion 32. In addition, since the head cylindrical portion 32 includes a relatively thick portion at the outer periphery on the −Y direction side with respect to the detection coil 1, the strength of the head cylindrical portion 32 is easily maintained. As a result, the proximity sensor 100 can improve the detection accuracy while maintaining mechanical strength. In addition, since the head cylindrical portion 32 and the cap portion 35 including the detection surface 30 are separated from each other, a degree of difficulty in processing the portion of the head cylindrical portion 32 on the +Y direction side to which the cap portion 35 is attached to be thinner is reduced. Further, an inner periphery of the end portion of the head housing 3 on the +Y direction side is used for positioning the detection coil 1. The position accuracy of the detection coil 1 with respect to the head housing 3 greatly influences the detection distance based on the detection surface 30. Thus, when the end portion of the head housing 3 on the +Y direction side can be processed with high accuracy with the configuration in which the head cylindrical portion 32 and the cap portion 35 are separated from each other, the detection distance of the proximity sensor 100 can be increased.

The detection coil 1 preferably generates a magnetic field at an effective frequency of 2 kHz or more and 200 kHz or less. A portion including the detection surface 30 preferably has a thickness of 1.0 mm or less.

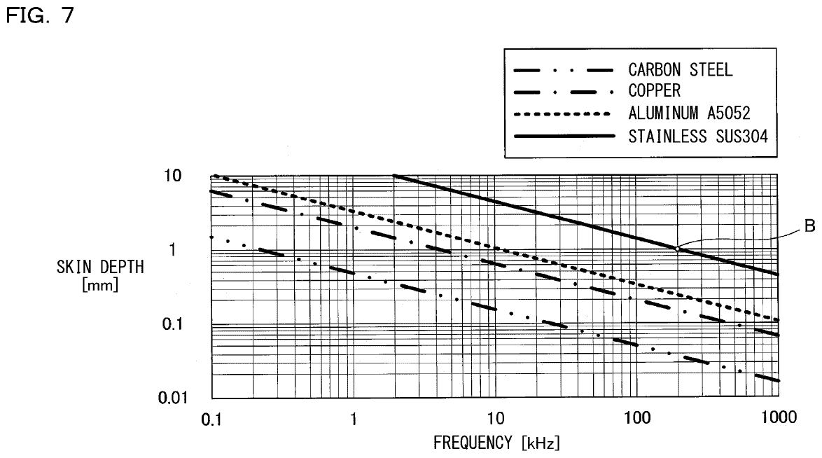

Next, the reason for the preferable effective frequency (2 kHz or more and 200 kHz or less) of the magnetic field and the preferable thickness (1.0 mm or less) of the portion including the detection surface 30 will be described in detail with reference to FIG. 7. FIG. 7 is a double logarithmic graph with a horizontal axis and a vertical axis as a frequency-skin depth, and a schematic view for explaining the double logarithmic graph.

As illustrated in the double logarithmic graph of FIG. 7, the higher the frequency, the smaller the skin depth. In other words, the lower the frequency, the greater the skin depth. Since the skin depth indicates a length in which a magnetic flux line having a certain intensity toward a member made of a certain material attenuates to a certain intensity, the lower the frequency, the more difficult the attenuation, and the skin depth increases. In addition, the more easily the magnetic flux line passes through the member, the less easily the magnetic flux line attenuates, and thus, the skin depth increases.

In order to reduce the attenuation of the magnetic flux by the detection surface 30 made of metal, it is preferable to generate a magnetic field at a low frequency. However, when the frequency of the generated magnetic field is low, it is difficult to grasp a change in the magnetic field when the magnetic flux passes through the detection object D, and there is a risk that the detection object is reduced.

On the other hand, the pulse type or the relatively low-frequency sine sinusoidal type generally has an effective frequency of 200 kHz or less. In a case where an upper limit of the effective frequency is 200 kHz, that is, in a case where the frequency is 200 kHz (point B in FIG. 7) or less, a skin depth of stainless steel (SUS304) exceeds 1 mm. Accordingly, in a case where the portion including the detection surface 30 is made of stainless steel (SUS304) having relatively high mechanical strength, when an upper limit of the thickness is 1 mm, both mechanical strength and reduction in magnetic flux attenuation due to the member constituting the detection surface 30 can be achieved. Note that, in the present embodiment, SUS304 is used as the stainless steel, but the stainless steel is not limited to SUS304, and another stainless steel may be used.

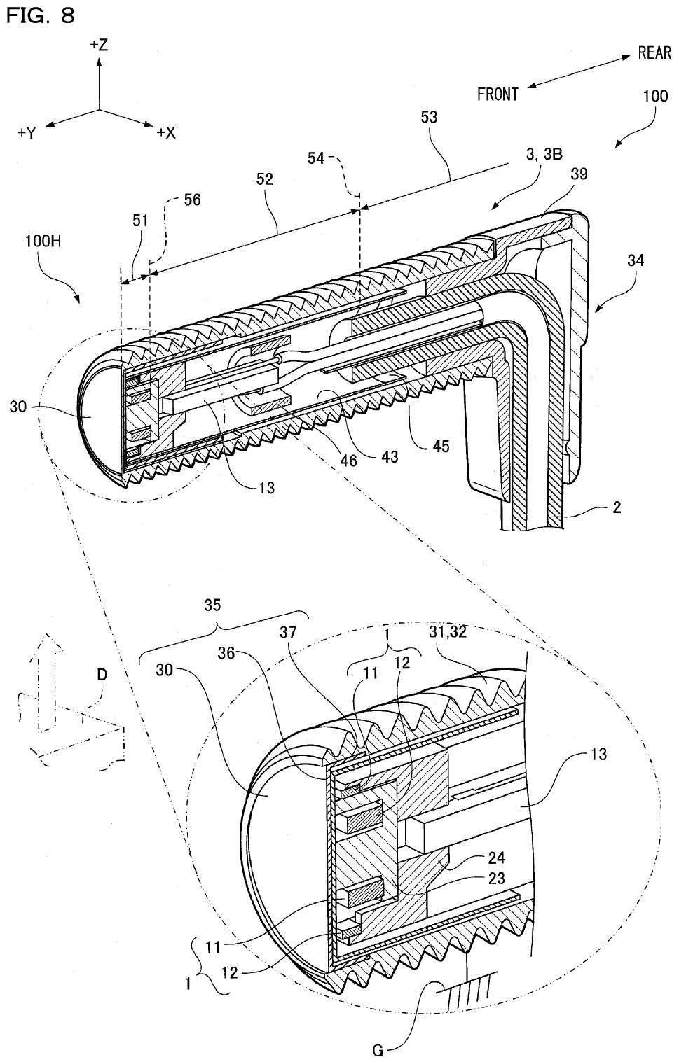

Next, a filler with which the head housing 3 is filled will be described in detail with reference to FIG. 8. FIG. 8 is a perspective view of a longitudinal section of the head housing 3. In FIG. 8, illustration and reference numeral of the filler are omitted in order to prioritize visibility, but the filler is filled in a portion indicated as a space inside the head housing 3.

As illustrated in FIG. 8, the proximity sensor 100 includes the detection coil 1, the power supply cable 2, and the metal head housing 3, and the head housing 3 is filled with the filler.

The detection coil 1 generates a magnetic field for detection. The power supply cable 2 is a member for supplying power to the detection coil 1. The head housing 3 is made of metal and houses the detection coil 1. The head housing 3 is filled with the filler, and the filler is filled to fill a periphery of the detection coil 1 housed in the head housing 3. As the filler, an adhesive and an additive having a relative permittivity lower than that of the adhesive are mixed.

The proximity sensor 100 is a sensor that detects the detection object D, which is a metal body, by using an induced current. The presence or absence and the position of the detection object D are detected based on the change in the detection current generated in the detection coil 1. The longer the distance between the detection coil 1 and the detection object D, the weaker the change in the detection current. Thus, in order to increase the detection distance of the proximity sensor 100, it is necessary to capture a weak change in the detection current. When a component of a noise current is added to the detection current, even though the noise current is weak, there is a risk that the detection accuracy decreases.

More specifically, since power is supplied to the detection coil 1 to the head 100H via the power supply cable 2, the power supply cable 2 is electrically connected to the detection coil 1. Thus, the power supply cable 2 can be a path into which the noise current that influences the change in the detection current of the detection coil 1 flows.

Meanwhile, the external member E to which the head housing 3 is fixed is often grounded to a ground G. This is because the external member E is often a part of a device including the proximity sensor 100 in the present embodiment, and such a device is often connected to the ground G for accident prevention. Thus, in many cases, the head housing 3 fixed to the external member E is grounded to the ground G, and a current generated in the head housing 3 itself flows to the ground G. When the head housing 3 is grounded, the power supply cable 2 and the head housing become circuits via the ground G, and there is a risk that the noise current flows into the head 100H from the power supply cable 2. Thus, it is preferable to minimize capacitive coupling between the head housing 3, the power supply cable 2, and a current circuit from the power supply cable 2 to the detection coil 1. For example, air is present.

However, the head housing 3 is filled with the filler to improve mechanical strength. There is a risk that the capacitive coupling of the filler causes the current to flow between the head housing 3 and the current circuit between the power supply cable 2 and the detection coil 1. That is, due to the capacitive coupling of the filler, the power supply cable 2, the current circuit between the power supply cable 2 and the detection coil 1, and the head housing 3 constitute the current circuit via the ground G, and thus, there is a risk that noise current flows from the power supply cable 2 into the head 100H. When this noise current influences the change in the detection current flowing through the detection coil 1, there is a risk that the accuracy of detection by the proximity sensor 100 decreases.

The proximity sensor 100 of the present embodiment has a relative permittivity lower than a case where the filler to be filled includes only an adhesive. Thus, capacitive coupling hardly occurs between the head housing 3 and the current circuit between the power supply cable 2 and the detection coil 1. Accordingly, the noise current hardly flows into the head 100H. Accordingly, the proximity sensor 100 can achieve both mechanical strength by the filler and detection accuracy. Note that, in the present embodiment, the head housing 3 is filled with the filler, but the head housing 3 is not limited to the entire head housing 3. Only the portion on the +Y direction side including the detection coil 1 may be filled in the head housing 3. In addition, the entire head housing 3 in a circumferential direction with the Y-axis direction as a center line does not need to be filled, and at least an inner space including the detection coil 1 may be filled. In this case, an air layer may be present between the filled portion and the head housing 3.

The filler has a relative permittivity of 3.7 or less. The relative permittivity of the filler is 3.7 or less, and thus, capacitive coupling hardly occurs between the head housing 3 and the current circuit between the power supply cable 2 and the detection coil 1. Accordingly, the proximity sensor 100 can reduce the decrease in the detection accuracy due to noise flowing in from the power supply cable 2.

The internal space of the head housing 3 has a first space including the detection coil 1 in the Y-axis direction and a second space not including the detection coil 1 and positioned on the −Y-direction side with respect to the first space. A filler filled in the first space has a relative permittivity lower than a filler filled in the second space.

That is, in a case where the filler filled in the first space is a first filler and the filler filled in the second space is a second filler, a relative permittivity of the first filler is lower than a relative permittivity of the second filler.

With such a configuration, capacitive coupling between the current circuit between the power supply cable 2 and the detection coil 1 and the head housing 3 easily occurs in the second space filled with the second filler, that is, the space not including the detection coil 1. Accordingly, even though the current circuit including the power supply cable 2, the head housing 3, and the ground is formed, the current easily flows in a path through the second space not including the detection coil 1. Accordingly, even though the noise current enters the head 100H from the power supply cable 2, the noise current hardly flows near the detection coil 1. Accordingly, the influence of the noise current flowing from the power supply cable 2 on the detection current is reduced. In addition, since a material of the second filler can be selected with priority given to hardness rather than relative permittivity, durability of the entire head 100H can be improved.

The head housing 3 has the detection surface 30 that is a surface for detecting the detection object D. An end portion of the second space on the +Y direction side is filled with the first filler and the second filler to be positioned on the −Y-axis direction side (rear side) with respect to the −Y-axis direction end (rear end) 56 of the detection coil 1.

Accordingly, even though the noise current enters from the power supply cable 2, the noise current hardly flows near the detection coil 1. Accordingly, the influence of the noise current flowing from the power supply cable 2 on the detection current is reduced.

The proximity sensor 100 further includes a conductive electric shield 43. The electric shield 43 covers the detection coil 1 in the circumferential direction with the Y-axis direction as the center line. A +Y direction-side end of the second space is filled with the first filler and the second filler to be positioned on the −Y direction side (rear side) with respect to a −Y direction-side end (rear end) 54 of the electric shield 43.

The electric shield 43 is provided to prevent external noise to the detection coil 1. Thus, the electric shield 43 is provided such that the detection coil 1 is sufficiently covered in the Y-axis direction. Accordingly, a boundary between the first space and the second space is positioned on the −Y direction side with respect to the −Y direction-side end of the electric shield 43, a distance between the detection coil 1 and the boundary between the first space and the second space in the Y-axis direction becomes long. Accordingly, the influence of the noise current flowing from the power supply cable 2 on the detection current is reduced.

The space filled with the filler in the head housing 3 is partitioned into a front space 51, a middle space 52, and a rear space 53 in the Y-axis direction. The front space 51 is a space on the front side (+Y direction side) with respect to the rear end 56 that is the −Y direction side end of the detection coil 1 inside the head housing 3. The middle space 52 is a space on the rear side (−Y direction side) with respect to the rear end 56 of the detection coil 1 and on the front side (+Y direction side) with respect to the rear end 54 which is the −Y direction side end of the electric shield 43 inside the head housing 3. The rear space 53 is a space on the rear side (−Y direction side) with respect to the rear end 54 of the electric shield 43 inside the head housing 3.

As an example, the front space 51 is filled with the first filler, and the middle space 52 and the rear space 53 are filled with the second filler. In this case, the first space is the front space 51, and the second space is the middle space 52 and the rear space 53. That is, the boundary between the first space and the second space is a boundary 56 between the front space 51 and the middle space 52.

As another example, the front space 51 and the middle space 52 are filled with the first filler, and the rear space 53 is filled with the second filler. In this case, the first space is the front space 51 and the middle space 52, and the second space is the rear space 53. That is, the boundary between the first space and the second space is a boundary 54 between the middle space 52 and the rear space 53.

The filler is a mixture of an adhesive and an additive. The adhesive is, for example, silicone-based, urethane-based, or polyethylene-based. The additive has a relative permittivity lower than the adhesive. A material of the additive is, for example, at least one of fluorine, polyimide, chlorine, polyethylene, acryl, urethane, boron nitride, air, and vacuum filler. Examples of a shape of the additive include a platelet type of primary particles, an agglomerates type of granulation, and a flake type.

The hardness Shore after curing of the filler is preferably D0 or more, and more preferably D80 or more. This is because, the hardness Shore after curing of the filler is D80 or more, and thus, the mechanical strength of the proximity sensor 100 can be sufficiently improved.

The proximity sensor 100 may further include a member 46 that fixes the head board 13 inside the head cylindrical portion 32. The proximity sensor 100 can stabilize assembly by the member 46 that fixes the head board 13 inside the head cylindrical portion 32.

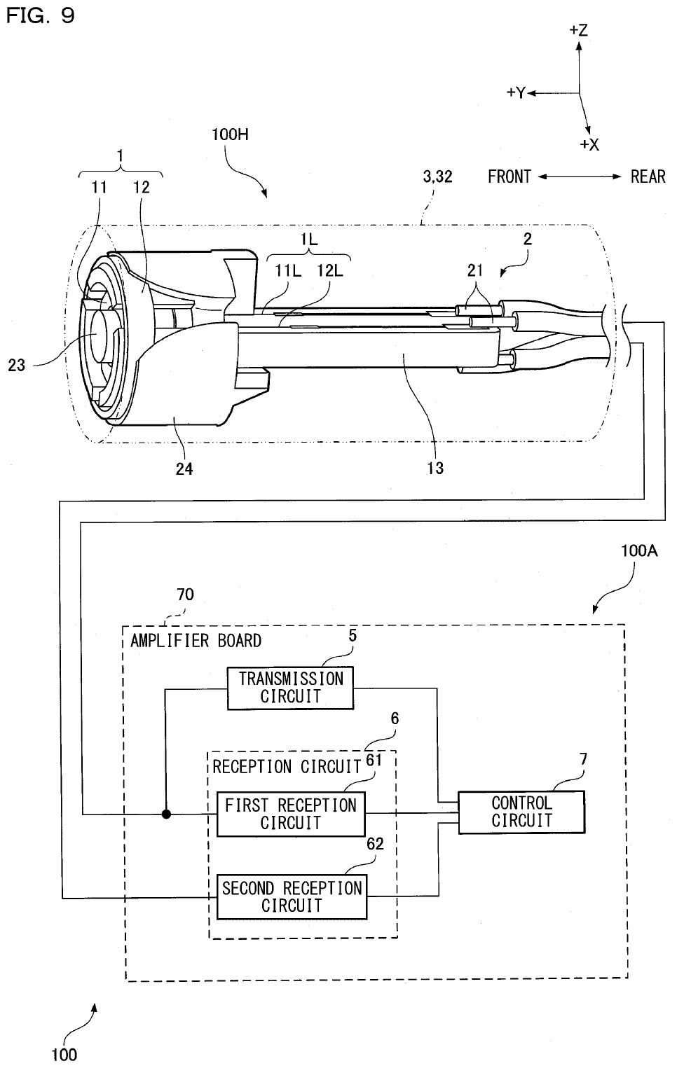

Details of the detection coil 1 will be described below with reference to FIG. 9. FIG. 9 is an enlarged perspective view illustrating the detection coil 1 and a device related to the detection coil 1. In FIG. 9, configurations unnecessary for the description of FIG. 9 are omitted in order to prioritize visibility.

As illustrated in FIG. 9, the detection coil 1 includes a coil wire 1L. The power supply cable 2 has a core wire 21. The proximity sensor 100 further includes the head board 13. The head board 13 is housed in the head housing 3 and extends along the longitudinal direction (front-back direction). A circuit that electrically connects the coil wire 1L and the core wire 21 is provided in the head board 13. That is, the head board 13 can be said to be a member that electrically connects the coil wire 1L and the core wire 21.

Since both the coil wire 1L and the core wire 21 are flexible linear members, handling at the time of assembly is complicated. Since the coil wire 1L and the core wire 21 are housed in the head housing 3 via the head board 13 having a certain degree of hardness, the assembly of the proximity sensor 100 is easily stabilized.

The proximity sensor 100 further includes a ferrite core 23 and a core holder 24. The coil wire 1L is wound around the ferrite core 23. The core holder 24 holds the ferrite core 23. The head board 13 is fixed to the core holder 24. In a case where the ferrite core 23 and the head board 13 are not fixed to each other and are freely movable, there is a risk that a load is applied to the coil wire 1L and the coil wire 1L is disconnected by separating the ferrite core 23 and the head board 13 by a certain amount or more at the time of assembly. Since the ferrite core 23 and the head board 13 are fixed via the core holder 24, the risk that the coil wire 1L is disconnected at the time of assembly is reduced.

The coil wire 1L includes first coil wires 11L and second coil wires 12L different from the first coil wires 11L. The detection coil 1 includes a first coil 11 around which the first coil wires 11L are wound, and a second coil 12 around which the second coil wires 12L are wound outside the first coil 11. Note that, there are two first coil wires 11L extending from the first coil 11, one first coil wire 11L is connected to a surface of the head board 13 on the +Z direction side as illustrated in FIG. 9, and the other first coil wire 11L is connected to a surface of the head board 13 on the −Z direction side. In the present embodiment, the two first coil wires 11L are connected to different surfaces of the head board 13, but may be connected to the same surface. In addition, there are two second coil wires 12L extending from the second coil 12, one of the second coil wires 12L is connected to a surface of the head board 13 on the +Z direction side as illustrated in FIG. 9, and the other of the second coil wires 12L is connected to a surface of the head board 13 on the −Z direction side. In the present embodiment, the two second coil wires 12L are connected to different surfaces of the head board 13, but may be connected to the same surface.

Since a positional relationship between the first coil 11 and the second coil 12 is different, a detection current generated in the first coil 11 and a detection current generated in the second coil 12 are influenced by surrounding metal bodies such as the detection object D and the external member E in different ways. That is, the first coil 11 and the second coil 12 have characteristics. Accordingly, the proximity sensor 100 includes the first coil 11 and the second coil 12 as the detection coil 1, and thus, the detection accuracy can be improved.

In the configuration in which the proximity sensor 100 includes the first coil 11 and the second coil 12 as the detection coil 1, there is a risk that detection accuracy is influenced by a relative positional relationship between the first coil 11 and the second coil 12. Since the first coil 11 and the second coil 12 are often positioned on an inner surface of the portion of the head housing 3 on the +Y direction side, there is a high demand for processing accuracy of the portion of the head housing 3 on the +Y direction side for detection accuracy. As described above, in a case where the head cylindrical portion 32 and a metal cap 35 (metal cap portion 35) including the detection surface 30 are made of different members, since a degree of difficulty in high-precision processing of the portion of the head housing on the +Y direction side is reduced, it is particularly effective in the configuration in which the proximity sensor 100 includes the first coil 11 and the second coil 12. In addition, since the second coil 12 is positioned outside the first coil 11, the second coil 12 is positioned at a position close to an inner peripheral surface of the head housing 3, that is, an inner surface of the head cylindrical portion 32. Accordingly, the portion of the head housing 3 on the +Y direction side is required to have processing accuracy not only near the center line of the head cylindrical portion 32 but also to a peripheral portion by the center line. As described above, in a case where the head cylindrical portion 32 and the metal cap 35 including the detection surface 30 are made of different members, since the degree of difficulty in high-precision processing of the portion of the head housing on the +Y direction side is reduced, the configuration in which the proximity sensor 100 includes the first coil 11 and the second coil 12 disposed outside the first coil 11 is particularly effective.

The proximity sensor 100 includes the transmission circuit 5, the reception circuit 6, and the control circuit 7. The transmission circuit 5 supplies the pulse-shaped excitation current to the first coil 11. The reception circuit 6 detects the detection current generated in both the first coil 11 and the second coil 12. The control circuit 7 detects the presence or absence or the position of the detection object D based on a reception signal from the reception circuit 6 that has detected the detection current. Since the detection current changes in accordance with a change in the magnetic field, the change in the magnetic field is reflected in the reception signal from the reception circuit 6. The control circuit 7 outputs a result of detecting the presence or absence or the position of the detection object D.

The detection coil 1 includes the first coil 11 and the second coil 12 different from the first coil 11. Since the first coil 11 and the second coil 12 are separate from each other, the dispositions in the head housing 3 are different. Thus, the change in the detection current due to the change in the magnetic field is different between the detection current of the first coil 11 and the detection current of the second coil 12. The reception circuit 6 transmits the detection current (hereinafter, first detection current) generated in the first coil 11 and the detection current (hereinafter, second detection current) generated in the second coil 12 to the control circuit in a state of being independent from each other. The control circuit 7 detects the presence or absence and the position of the detection object D based on a first reception signal based on the first detection current and a second reception signal based on the second detection current. At this time, the first reception signal and the second reception signal have different signal changes with respect to a change in a certain magnetic field. For example, even in a case where the magnetic field is changed by both the detection object D of the metal body and the external member E of the metal body, a plurality of coils having different dispositions are used as the detection coil 1 such that the magnetic field change by the detection object D of the metal body is easily reflected in the first reception signal and the magnetic field change by the external member E of the metal body is easily reflected in the second reception signal, and thus, various types of information around the head housing 3 can be acquired. Accordingly, in the detection in the proximity sensor 100, the control circuit 7 processes the first reception signal based on the detection current generated in the first coil 11 and the second reception signal based on the detection current generated in the second coil 12 in consideration of the characteristics of the first coil 11 and the second coil 12, and thus, the detection accuracy can be improved.

The reception circuit 6 includes a first reception circuit 61 that detects the detection current generated in the first coil 11 and a second reception circuit 62 that detects the detection current generated in the second coil 12. According to this configuration, the first detection current and the second detection current can be simultaneously transmitted to the control circuit 7 while being independent from each other. Thus, since a period during which the control circuit 7 receives the first reception signal and a period during which the control circuit 7 receives the second reception signal can be the same period, a time required to detect the presence or absence and the position of the detection object D by using the first reception signal and the second reception signal is shortened. In addition, calculation for correcting a difference between the period during which the first reception signal is acquired and the period during which the second reception signal is acquired becomes unnecessary. Accordingly, the reception circuit 6 includes the first reception circuit 61 and the second reception circuit 62, and thus, the detection accuracy of the proximity sensor 100 can be improved.

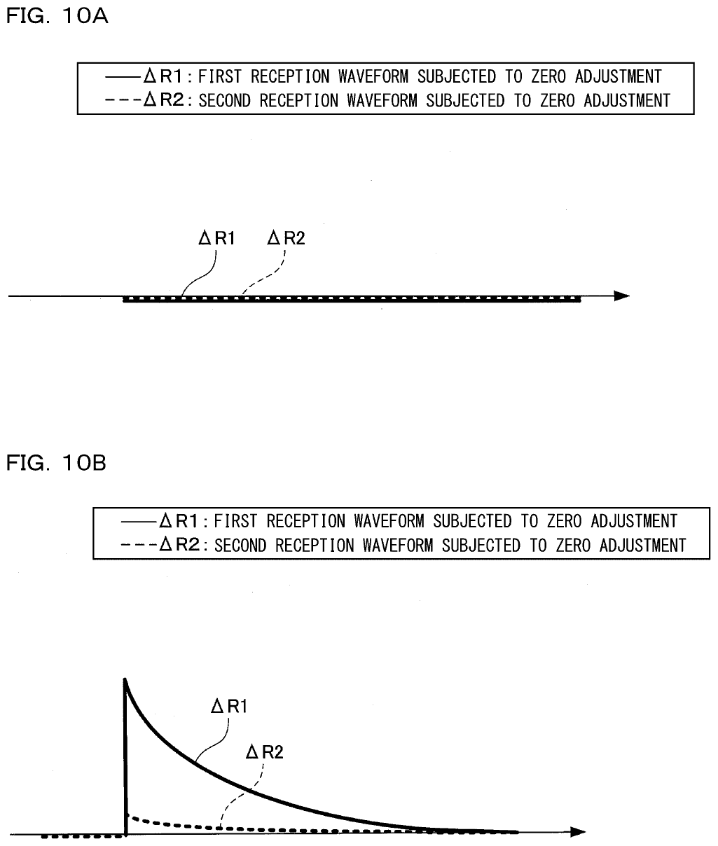

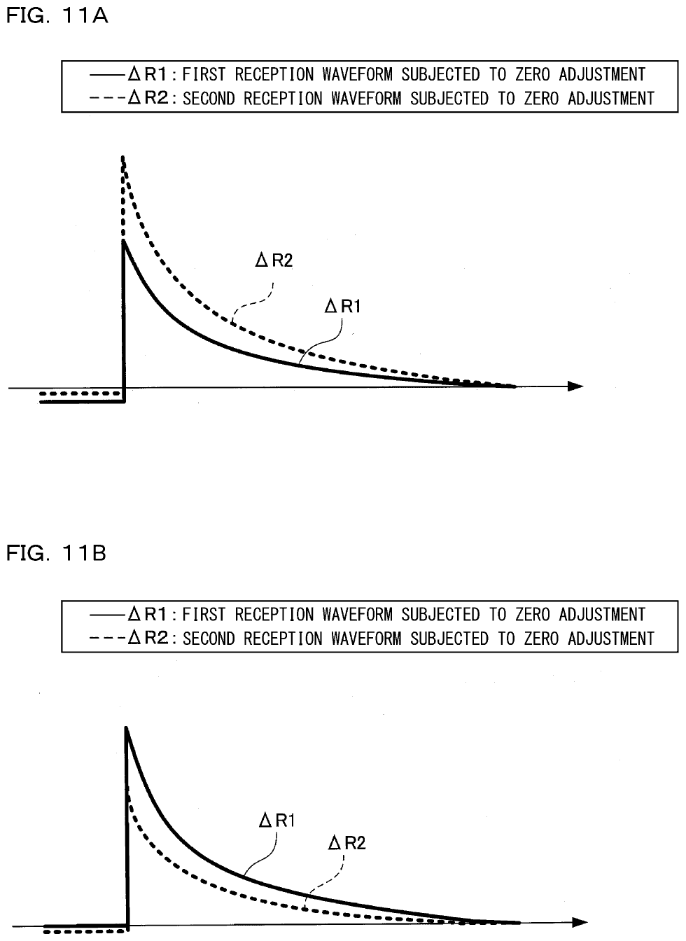

Here, the suppression of the influence of the metal body other than the detection object D will be described in detail with reference to FIGS. 10A to 11B. Hereinafter, a temporal change of the first reception signal may be referred to as a first reception waveform, and a temporal change of the second reception signal may be referred to as a second reception waveform. In addition, the first reception waveform and the second reception waveform may be collectively referred to as a reception waveform.

FIGS. 10A to 11B illustrate the first reception waveform (code ΔR1) subjected to zero adjustment and the second reception waveform (code ΔR2) subjected to zero adjustment. The zero adjustment in the present embodiment means that the signal intensity is subjected to zero adjustment in a case where there is no external member E of the metal body and the detection object D of the metal body is not within a detection range. Note that, in FIGS. 10A and 11B, a horizontal axis represents time, and a vertical axis represents a signal intensity of the reception waveform.

FIG. 10A is a graph representing an image of the reception waveform subjected to zero adjustment in a case where there is no external member E of the metal body and the detection object D is not within the detection range. As described above, since the waveform adjusted such that a value indicated by the waveform becomes zero in a case where there is no external member E of the metal body and the detection object D is not within the detection range is a waveform subjected to zero adjustment, both the first reception waveform and the second reception waveform indicate zero on the graph.

FIG. 10B is a graph representing an image of the reception waveform subjected to the zero adjustment in a case where there is no external member E and the detection object D is within the detection range. As illustrated in FIG. 10B, the amount of change in the signal intensity of the first reception waveform is larger than the amount of change in the signal intensity of the second reception waveform. This is because, the first coil 11 and the second coil 12 are disposed such that the first detection current generated in the first coil 11 is easily influenced by the magnetic field change by the detection object D within the detection range than the second detection current generated in the second coil 12.

FIG. 11A is a graph representing an image of the reception waveform subjected to the zero adjustment in a case where there is the external member E and the detection object D is not within the detection range. As illustrated in FIG. 11A, both the amount of change in the signal intensity of the first reception waveform and the amount of change in the signal intensity of the second reception waveform are large. This is because, both the first detection current generated in the first coil 11 and the second detection current generated in the second coil 12 are easily influenced by the magnetic field change by the external member E to which the head 100H is fixed. However, while the amount of change in the signal intensity of the first reception waveform illustrated in FIG. 10B is similar to the amount of change in the signal intensity of the first reception waveform illustrated in FIG. 11A, the amount of change in the signal intensity of the second reception signal illustrated in FIG. 11A is obviously larger than the amount of change in the signal intensity of the second reception signal illustrated in FIG. 10B. In addition, in FIG. 11A, the amount of change in the signal intensity of the second reception signal is larger than the amount of change in the signal intensity of the first reception signal. This is because, the first coil 11 and the second coil 12 are disposed such that the second detection current generated in the second coil 12 is easily influenced by the external member E than the first detection current generated in the first coil 11.

FIG. 11B is a graph representing an image of the reception waveform subjected to the zero adjustment in a case where the external member E is present and the detection object D is within the detection range. Similarly to FIG. 11A, since the head 100H is fixed to the external member E, both the amount of change in the signal intensity of the first reception waveform and the amount of change in the signal intensity of the second reception waveform are large as illustrated in FIG. 11B. However, unlike FIG. 11A, the amount of change in the signal intensity of the first reception signal is larger than the amount of change in the signal intensity of the second reception signal. In FIGS. 10A to 11B, the amount of change in the signal intensity of the first reception signal increases when there is the change in the magnetic field due to at least one of the external member E and the detection object D. Thus, it is difficult to detect the presence or absence and the position of the detection object D only from the first reception signal. In particular, in a case where the distance between the detection object D and the first coil 11 is long, since the amount of change in the signal intensity of the first signal due to the magnetic field change by the detection object D is similar to the amount of change in the signal intensity of the second signal due to the magnetic field change by the external member E, the detection accuracy easily decreases. On the other hand, in FIGS. 10A to 11B, when there is the change in the magnetic field by the external member E, the amount of change in the signal intensity of the second reception signal remarkably increases. Thus, the first reception signal and the second reception signal are combined, and thus, the accuracy of the detection of the presence or absence and the position of the detection object D can be improved.

More specifically, the calculation is performed by using a difference between the first reception waveform subjected to the zero adjustment and the second reception waveform subjected to the zero adjustment. The difference referred to herein is a value obtained by subtraction processing of the second reception waveform subjected to the zero adjustment from the first reception waveform subjected to the zero adjustment. According to this processing, the calculation result is a negative value in FIGS. 10A and 11A illustrating the reception signal in the absence of the detection object D, and the calculation result is a positive value in FIGS. 10B and 11B illustrating the reception signal in the presence of the detection object D. As described above, the detection accuracy of the proximity sensor 100 can be improved.

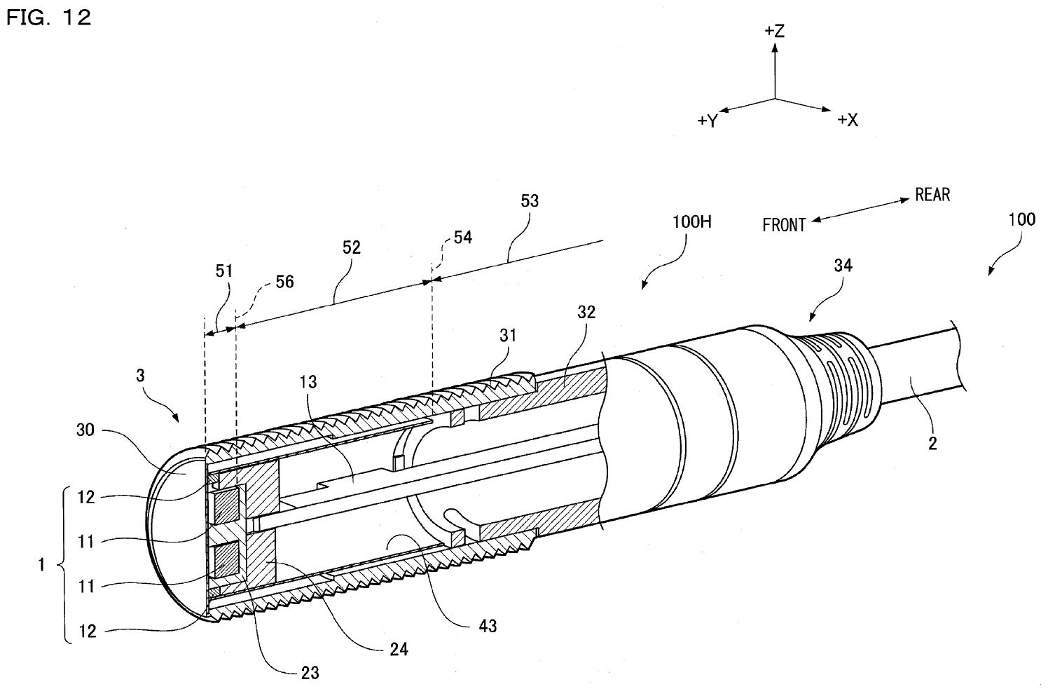

Hereinafter, another example of the detection surface 30 will be described with reference to FIG. 12. FIG. 12 is a partially cut perspective view of the cylinder-type proximity sensor 100. In FIG. 12, in order to give priority to visibility as in FIG. 8, the illustration and reference numeral of the filler are omitted, but the filler is filled in a portion indicated as a space inside the head housing 3. FIG. 12 illustrates arrows X, Y, and Z indicating three directions orthogonal to each other. The directions indicated by arrows X, Y, and Z all correspond to disposition postures of the proximity sensor 100, and the direction indicated by arrow X is referred to as an X-axis direction, the direction indicated by arrow Y is referred to as a Y-axis direction, and the direction indicated by arrow Z is referred to as a Z-axis direction. One of the directions along the X-axis direction is referred to as a +X direction, and the other is referred to as a −X direction. One of the directions along the Y-axis direction is referred to as a +Y direction, and the other is referred to as a −Y direction. One of the directions along the Z-axis direction is referred to as a +Z direction, and the other is referred to as a −Z direction. The normal direction of the detection surface 30 is the Y-axis direction, and the direction in which the detection surface 30 faces is the +Y direction.

The detection surface 30 illustrated in FIG. 12 is made of resin. In the proximity sensor 100 using the induced current, when the detection surface 30 is made of metal, there is a risk that the detection accuracy decreases due to the following reasons: an eddy current due to the magnetic field is generated on the detection surface 30 itself to generate noise; and a change in the detection current is generated due to the change in the magnetic field by the detection surface 30 itself. Thus, when the detection surface 30 is made of resin, the detection accuracy easily decreases. On the other hand, a resin member has lower strength than a metal member. Thus, the head housing 3 is filled with the filler, and thus, the mechanical strength is improved. As a result, both the detection accuracy and the strength can be achieved. Note that, the head 100H is easily capacitively coupled between the member including the detection surface 30 and the detection coil 1. Thus, the resin member is used as the detection surface 30, and thus, it is easy to prevent the noise current from flowing into near the detection coil 1.

However, when the head housing 3 is filled with the filler, as described above, there is a risk that the filler is capacitively coupled and the detection accuracy of the proximity sensor 100 decreases. More specifically, when the filler is capacitively coupled, the current circuit is formed by the ground connected to the power supply cable 2, the head housing 3, and the head housing 3, and thus, there is a risk that the noise current flows from the power supply cable 2 into the head 100H. Thus, it is particularly effective from the viewpoint of the detection accuracy of the proximity sensor 100 and the strength of the head 100H that the head housing 3 having the detection surface 30 made of resin is filled with the filler containing the additive having the relatively low relative permittivity. Further, the front space 51 positioned on the +Y direction side of the head housing 3 and including the detection coil 1 in the Y-axis direction is filled with the first filler containing the additive having the low relative permittivity, and the rear space 53 not including the detection coil 1 in the Y-axis direction is filled with the second filler having the higher relative permittivity and higher hardness than the first filler. According to this configuration, it is easy to achieve both the prevention of the decrease in the detection accuracy due to the influence of the noise having flowed into the head housing 3 on the detection current and the mechanical strength of the head 100H.

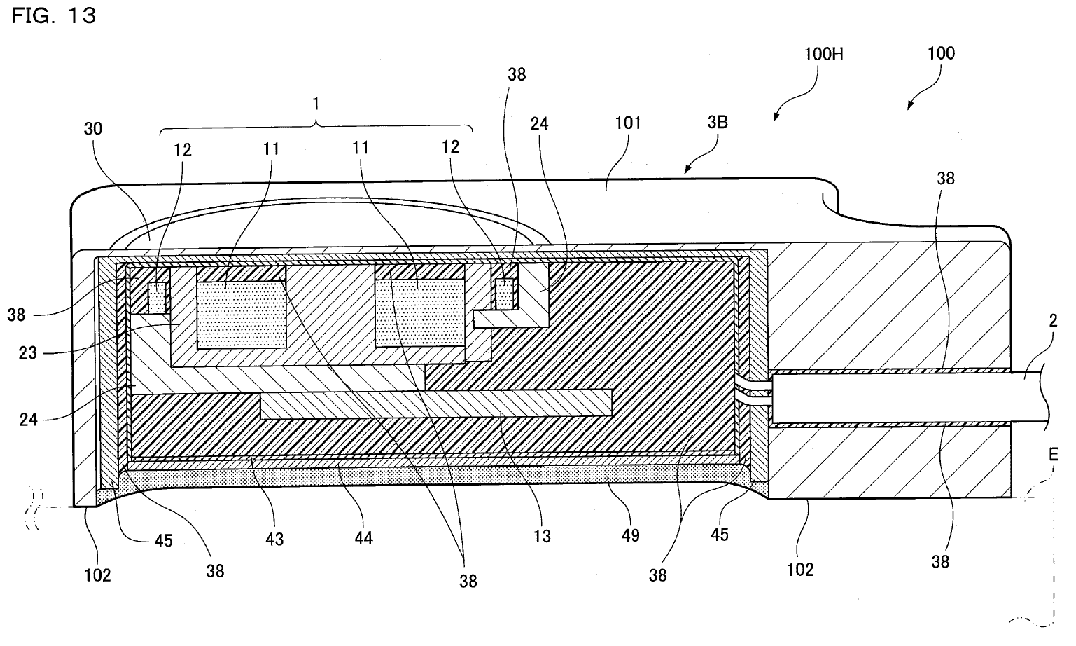

Hereinafter, the flat-type proximity sensor 100 will be described with reference to FIG. 13. FIG. 13 is an enlarged perspective view of a longitudinal section of the flat-type proximity sensor 100.

In the flat-type proximity sensor 100 illustrated in FIG. 13, a flat box-shaped head housing 3B is filled with a filler. The filler is denoted by reference numeral 38 in FIG. 13.

The box-shaped head housing 3B is not limited to a strict box shape, and may have a substantially box shape. The box-shaped head housing 3B has a first surface 101 and a second surface 102 different from the first surface 101. The first surface 101 includes the detection surface 30 that is the surface that detects the detection object D. The second surface 102 is installed (fixed) to come into contact with a surface of the external member E.

The proximity sensor 100 further includes the head board 13. The head board 13 is housed in the box-shaped head housing 3B and extends along the first surface 101. The head board 13 electrically connects the detection coil 1 and the power supply cable 2.

When the noise current influences the detection current generated in the detection coil 1, there is a risk that the inflow of the noise current from the power supply cable 2 to the head 100H due to the capacitive coupling of the filler described above causes a decrease in the detection accuracy of the proximity sensor 100. Thus, a portion where the capacitive coupling of the filler occurs and the noise current circuit can be formed is separated from the detection coil 1. However, in the head housing 3B, a circuit (corresponding to the head board 13) in which the power supply cable 2 and the detection coil 1 are electrically connected is disposed near the detection coil 1. Thus, in the flat-type proximity sensor 100, when the noise current flows into the head 100H from the power supply cable 2, there is a high possibility that the noise current influences the detection current, as compared with other types of proximity sensors 100. Thus, the configuration in which the relative permittivity of the filler is reduced such that the noise current from the power supply cable 2 hardly flows into the head 100H is particularly effective.

Incidentally, the embodiment is illustrative in all respects and is not restrictive. The scope of the invention is indicated not by the above description but by the claims, and it is intended that meanings equivalent to the claims and all changes within the scope are included. Among the configurations described in the embodiments, configurations other than the configurations described as one aspect of the invention in “Means for Solving Problems” are any configurations, and can be appropriately deleted and changed.

The invention provides the flat-type proximity sensor, and has industrial applicability.

What is claimed is:

1. A proximity sensor that detects a detection object, comprising:
a detection coil that generates a detection current;
a metal head housing that houses the detection coil;
a power supply cable having an electrical connection with the detection coil and connected to the metal head housing; and
a filler with which at least a part of an internal space of the metal head housing is filled to bury the detection coil,
wherein the filler includes an adhesive and an additive having a relative permittivity lower than a relative permittivity of the adhesive.

2. The proximity sensor according to claim 1, wherein the filler has a relative permittivity of 3.7 or less.

3. The proximity sensor according to claim 1, wherein a hardness Shore of the filler after curing is D0 degrees or more.

4. The proximity sensor according to claim 1,
wherein the detection coil is disposed on one side of the metal head housing in a predetermined direction,
the power supply cable is connected to the metal head housing on the other side of the metal head housing in the predetermined direction,
a first space including the detection coil is filled with a first filler as the filler, and
a second filler having a higher relative permittivity than that of the first filler fills on the other side in the predetermined direction with respect to the first space.

5. The proximity sensor according to claim 4,
wherein the metal head housing has a detection surface of which a normal direction is along the predetermined direction, and
an end portion of the first space on the other side is positioned on the other side with respect to an end of the detection coil on the other side.

6. The proximity sensor according to claim 4, further comprising:
a conductive electric shield that covers the detection coil,
wherein the metal head housing has a detection surface whose normal direction is along the predetermined direction, and
an end portion of the first space on the other side is positioned on the other side with respect to an end of the conductive electric shield on the other side.

7. The proximity sensor according to claim 1,
wherein the detection coil further includes
a first coil around which a first coil wire is wound,
a second coil in which a second coil wire different from the first coil wire is wound outside the first coil,
a transmission circuit that supplies a pulse-shaped excitation current to one of the first coil and the second coil,
a reception circuit that detects a first detection current generated in the first coil and a second detection current generated in the second coil, and
a control circuit that detects the detection object based on a reception signal from the reception circuit that has detected the first detection current and the second detection current, and
the control circuit outputs a result of detecting the detection object.

8. The proximity sensor according to claim 1,
wherein the metal head housing includes a detection surface that is positioned between the detection coil and the detection object and faces the detection object side when the detection object is detected, and
is formed by combining a metal body portion and a metal cap portion attached to an opening of the metal body portion and including the detection surface.

9. The proximity sensor according to claim 1, wherein the metal head housing is positioned between the detection coil and the detection object when the detection object is detected, and a detection surface facing the detection object is made of metal.

10. The proximity sensor according to claim 1, wherein the metal head housing is positioned between the detection coil and the detection object when the detection object is detected, and a detection surface facing the detection object is made of resin.

11. The proximity sensor according to claim 1, further comprising:
a head board housed in the metal head housing,
wherein the metal head housing has a substantially box shape including a first surface including a detection surface and a second surface that is different from the first surface and comes into contact with an external member when the metal head housing is installed on the external member,
a part of a circuit that electrically connects the detection coil and the power supply cable is implemented on the head board, and
the head board is disposed along the first surface.
